(19) United States
(12) Patent Application Publication
(10) Pub. No.: US 2017/0070192 A1
(43) Pub. Date: Mar. 9, 2017

(54) APPARATUS AND METHODS FOR REDUCING SUPPLY NOISE CONVERSION TO PHASE NOISE

(71) Applicant: Analog Devices, Inc., Norwood, MA (US)

(72) Inventors: Andrey Martchovsky, Fremont, CA (US); Roger Van Brunt, Santa Cruz, CA (US)

(21) Appl. No.: 15/143,951

(22) Filed: May 2, 2016

Related U.S. Application Data
(60) Provisional application No. 62/214,647, filed on Sep. 4, 2015.

(51) Int. Cl. H03B 1/04; H03L 7/18; H03L 7/099; H03L 7/089; H03B 5/04; H03B 5/12

(52) U.S. Cl. CPC H03B 1/04; H03B 5/04; H03B 5/1243; H03B 5/1215; H03B 5/1228; H03L 7/099; H03L 7/0891; H03L 7/18

(57) ABSTRACT

Provided herein are apparatus and methods for reducing supply noise conversion to phase noise. In certain configurations, voltage controlled elements such as varactors are used to control a VCO output frequency. A VCO transfer function relating supply voltage noise to a common node of a varactor gives rise to a transfer function of value a representing a push coefficient. An intentional amount of supply noise can be added to a tuning voltage by injecting it at a tuning port of the VCO. By splitting an integration capacitance in a loop filter, an integration capacitance can be divided among a capacitor divider to create a transfer function of value β representing a compensating coefficient. The injected noise from the capacitor divider can reduce VCO pushing by canceling the value α. When the value β is set equal to the value α, the VCO pushing can be reduced to within the estimation or measurement accuracy of the value α.

### BACKGROUND

Field

Embodiments of the invention relate to electronic circuits, and more particularly, to reducing VCO pushing in analog PLLs.

Description of the Related Technology

A voltage controlled oscillator (VCO) provides a signal with a voltage dependent frequency and can be used in radio frequency RF and in audio applications. In one application a VCO can be used in a phase locked loop (PLL) to convert a tuning voltage to a locked frequency. In a PLL, the VCO converts an error voltage from a phase detector and locks an output frequency. A frequency modulated signal can be demodulated by the PLL using the tuning voltage from the VCO.

In another application a VCO can be used as voltage to frequency converter. In this case a VCO with a predictable, highly linear relationship between the tuning voltage and frequency is used to provide an output voltage with a frequency as a function of the input tuning voltage.

### SUMMARY

In one aspect, an apparatus comprises a VCO and a filter. The VCO has a supply node configured to receive a supply voltage, a tuning port configured to receive a tuning voltage, and an output port configured to provide an output signal having a VCO output frequency. The filter has an output port electrically connected to the tuning port. The filter is configured to provide the tuning voltage having a filter supply injected component such that the filter supply injected component compensates for variations in the VCO output frequency in response to variations in the supply voltage.

The VCO and filter can be part of an integrated phase locked loop.

The VCO can further comprise a voltage controlled circuit element electrically connected between the output port and the tuning port such that an element voltage between the output port and the tuning port controls the VCO output frequency. The voltage controlled circuit element can be a varactor.

The output signal can have a VCO common mode supply noise component. Also, the filter supply injected component can be commensurate to the VCO common mode supply noise component such that variations in the element voltage are reduced.

The filter can further comprise a first impedance and a second impedance. The first impedance and the second impedance can be electrically connected in series to form a divider between the supply node and a common node such that the divider has a divider node electrically connected to the output port of the filter. The first and second impedances can be capacitors.

The divider can be configured to provide the filter supply injected component at the divider node such that the supply injected component depends, at least in part, upon the first impedance and the second impedance.

The divider can provide the filter supply injected component at the divider node based upon an intrinsic VCO transfer characteristic of the output signal at the output node of the VCO to a noise signal at the supply node.

In another aspect an apparatus comprises a VCO and a filter. The VCO comprises a supply node, a tuning port, a first output port, and a second output port. The filter comprises a first impedance and a second impedance. The tuning port is configured to receive a tuning voltage. The first output port is configured to provide a first output signal having a VCO output frequency. The second output port is configured to provide a second output signal complementary in phase to the first VCO output signal and having the VCO output frequency. The first impedance is electrically connected between the supply node and the tuning port; and the second impedance is electrically connected between the ground node and the tuning port. The first impedance and the second impedance are configured to provide the tuning voltage having a filter supply injected component from the supply rail onto the tuning port; and the filter supply injected component reduces a supply push of the VCO.

The VCO can further comprise a first voltage controlled circuit element and a second voltage controlled circuit element. The first voltage controlled circuit element can be electrically connected between the first output port and the tuning port, and the second voltage controlled circuit element can be electrically connected between the second output port and the tuning port. The VCO output frequency can be determined, at least in part, by a first differential voltage between the first output port and the tuning port and a second differential voltage between the second output port and the tuning port.

The first voltage controlled circuit element and the second voltage controlled circuit element can be varactors.

The first output signal can have a VCO common mode supply injected component; and the second output signal can have the VCO common mode supply injected component. The filter supply injected component can be commensurate to the VCO common mode supply injected component such that variations in the first differential voltage and the second differential voltage due to variations in the VCO common mode supply injected component are reduced.

The filter can be interposed between a phase locked loop charge pump and the VCO such that the tuning voltage has a PLL tuning component. The first differential voltage and the second differential voltage can vary in response to variations in the PLL tuning component such that the PLL tuning component controls the VCO output frequency.

The first impedance can be a capacitor having a first capacitance, and the second impedance can be a capacitor having a second capacitance. A filter response of the filter can be determined, at least in part, by the sum of the first and the second capacitance. The first impedance and the second impedance can be electrically connected in series to form a capacitor divider between the supply node and the ground node. The capacitor divider can be configured to provide the tuning voltage having a filter supply injected component from the supply rail onto the tuning port.

The filter supply injected component can depend upon the first capacitance, the second capacitance, and the supply voltage. The capacitor divider can provide the filter supply injected component based upon a first transfer characteristic of the first output signal to a noise signal of the power supply node. The first transfer characteristic of the first output signal to the noise signal of the power supply node can be equivalent to a second transfer characteristic of a second output signal to a noise signal of the power supply node.

In another aspect, a voltage controlled oscillator circuit comprises an oscillator and a filter. The oscillator receives a supply voltage with a variable component and an input voltage and provides an output signal having a frequency. The oscillator includes an impedance circuit with at least one active impedance component that has a variable impedance based upon the input voltage and the supply voltage such that the input voltage and the supply voltage varies the impedance of the active impedance component and thereby varies the frequency of the output signal. The filter provides the input voltage to the oscillator, and the filter receives the supply voltage. A filtered component of the supply voltage is provided to the impedance circuit from the filter so as to offset the variable component of the supply voltage received by the at least one active impedance component.

The filter can include a capacitive filter that provides a capacitance between the supply voltage and the input voltage and between the input voltage and the ground.

### BRIEF DESCRIPTION OF THE DRAWINGS

These drawings and the associated description herein are provided to illustrate specific embodiments of the invention and are not intended to be limiting.

FIG. 1A is an example VCO used in the teachings herein.

FIG. 1B is a common mode equivalent schematic of the VCO of FIG. 1A according to the teachings herein.

FIG. 1C is a small signal impedance schematic of the common mode equivalent schematic in FIG. 1B according to the teachings herein.

FIG. 2 is a system diagram of a VCO according to the teachings herein.

FIG. 3 is a system diagram of a PLL with a VCO model and filter according to the teachings herein.

FIG. 4A is a system diagram of a filter showing a system-level synthesis approach with a compensating coefficient according to the teachings herein.

FIG. 4B is an impedance schematic of a filter according to an embodiment.

FIG. 4C is an impedance schematic of a filter according to another embodiment.

FIG. 4D is a circuit schematic of a filter based on the embodiment of FIG. 4B.

FIG. 5 is a relative plot of simulated phase noise vs. carrier offset frequency comparing an embodiment of the teachings herein.

FIG. 6 is a top level diagram of a PLL including a loop filter with a capacitor divider in accordance with the teachings herein.

FIG. 7 is a graph of VCO supply push gain K_{VDD} versus compensation coefficient β according to an embodiment.

### DETAILED DESCRIPTION OF EMBODIMENTS

The following detailed description of embodiments presents various descriptions of specific embodiments of the invention. However, the invention can be embodied in a multitude of different ways as defined and covered by the claims. In this description, reference is made to the drawings in which like reference numerals may indicate identical or functionally similar elements.

Voltage controlled oscillators (VCOs) can be used to provide an output signal with an oscillation frequency dependent upon an applied tuning voltage. In order to provide a useful output signal, the VCO requires a power supply such as a battery or a stable DC voltage source. There is an intended relationship between the applied tuning voltage and the signal output frequency. However, there can also be an unintended relationship between the supply voltage and the oscillator frequency.

When the signal output frequency of the VCO is sensitive to supply voltage, a change in the supply voltage causes a change in the output frequency. This is referred to as VCO pushing where unavoidable noise in the supply voltage induces phase noise in the output frequency. Measurements of VCO pushing are expressed in units of frequency per volts with either a positive or negative coefficient. In addition, as those of ordinary skill in the art can appreciate, VCO pushing can also be referred to as “supply injected noise conversion to phase noise”, “supply pushing”, “frequency pushing”, or “VCO supply pushing”.

One approach to reducing VCO pushing is to reduce the amount of supply noise by using off chip decoupling capacitors or an on-chip integrated low-dropout regulator (LDO) with good power supply rejection ratio (PSRR). However, an LDO is a voltage regulator which consumes additional chip area and consumes power; moreover, off chip decoupling capacitors add an additional component cost and also consume space.

Accordingly, there is a need for reducing VCO pushing in an area efficient manner without the use voltage regulators or decoupling capacitors.

Provided herein are apparatus and methods for reducing supply noise conversion to phase noise. Reducing supply noise conversion to phase noise refers to reducing VCO pushing and is implemented by intentionally introducing noise on a tuning node of the VCO so that it counteracts noise or a noise signal across a voltage controlled element, such as a varactor. The noise or the noise signal across the voltage controlled element can be the difference between a common mode voltage at a first terminal and the intentionally introduced noise at the tuning node. As will be shown from a mathematical analysis, the intentional introduction of noise on the tuning node can be realized by creating a filter circuit which can compensate for supply push. This in turn leads to a general circuit synthesis approach for creating a filter which compensates for supply push in a VCO.

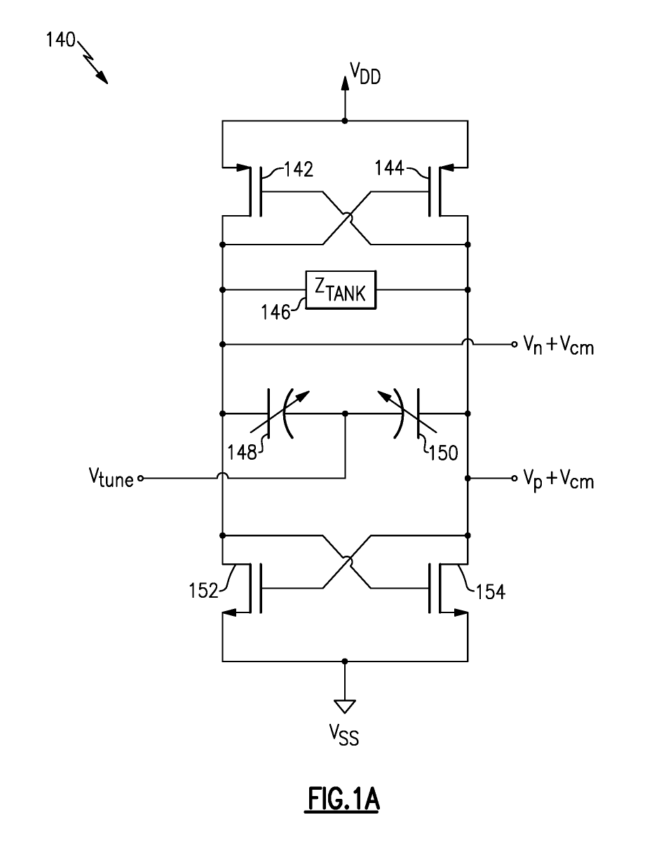

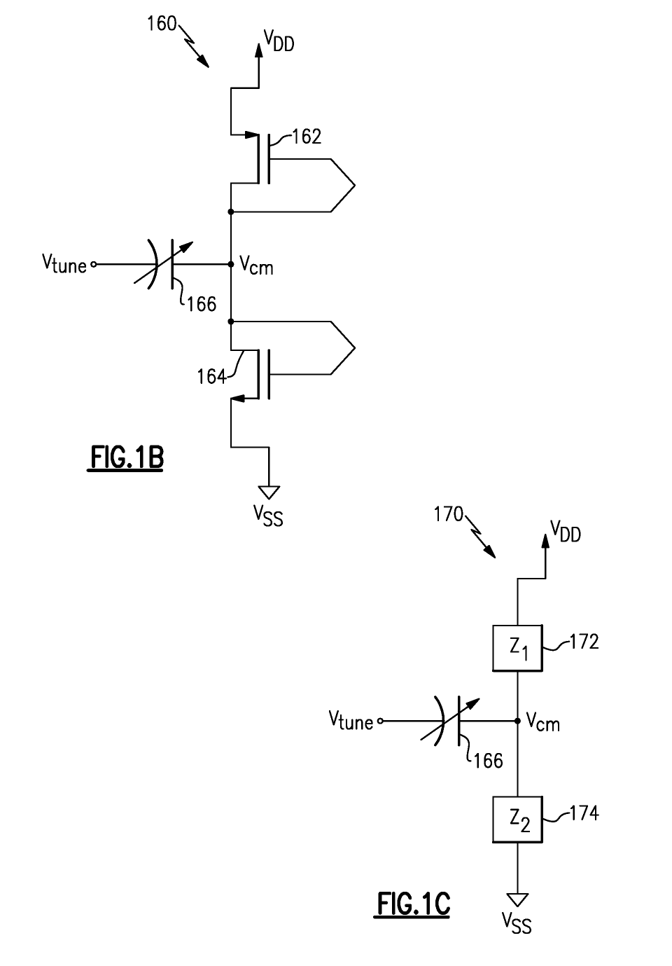

FIG. 1A is an example VCO 140 used in the teachings herein. The VCO 140 is a Van der Pol VCO. The VCO 140 has a cross coupled n-channel field effect transistor (NFET) pair at the body-connected sources of an NFET 152 and an NFET 154. The NFET 152 and NFET 154 are cross coupled such that a gate of NFET 152 is electrically connected to a drain of NFET 154 while a gate of NFET 154 is electrically connected to a drain of NFET 152. A source of NFET 152 and a source of NFET 154 are connected to a first supply V_{SS}. The drain of NFET 152 is further connected to an inverting output port while the drain of NFET 154 is connected to a noninverting output port.

The VCO 140 also has a cross coupled p-channel field effect transistor (PFET) pair at the body-connected sources of a PFET 142 and a PFET 144. The PFET 142 and PFET 144 are cross coupled such that a gate of PFET 142 is electrically connected to a drain of PFET 144 while a gate of PFET 144 is electrically connected to a drain of PFET 142. A source of PFET 142 and a source of PFET 144 are connected to a second supply V_{DD}. The drain of PFET 142 is further connected to the inverting output port while the drain of PFET 144 is connected to the noninverting output port.

A resonant tank circuit 146 is electrically connected between the noninverting output port and the inverting output port. A varactor 148 is electrically connected between the inverting output port and a tuning port, and a varactor 150 is electrically connected between the noninverting output port and the tuning port.

The noninverting output port provides a noninverting oscillator signal Vₚ plus a common mode signal V_{CM}. The inverting output port provides an inverting oscillator signal Vn plus the common mode signal V_{CM}. The noninverting oscillator signal Vₚ and the inverting oscillator signal Vn have a frequency of oscillation determined in part by the properties and impedances of the NFETs 152 and 154, the PFETs 142 and 144, the tank circuit 146, and the varactors 148 and 150. A tuning voltage Vtune can be applied to the tuning port so as to vary a capacitance of the varactors 148 and 150; in doing so, the frequency of oscillation is controlled by the tuning voltage Vtune.

Although not shown in FIG. 1A, the tank circuit 146 can be realized using energy storage elements including capacitors, inductors, and/or interconnect circuitry such as stripline.

FIG. 1B is a common mode equivalent schematic 160 of the VCO of FIG. 1A according to the teachings herein. FIG. 1B shows an NFET 164, a PFET 162, and a varactor 166. The common mode schematic 160 can be used as an analytical common mode representation of the VCO 140 of FIG. 1A. In the common mode schematic 160, the NFET 164 represents the NFET 152 and the NFET 154, whereby a gate and a drain of the NFET 164 connect to a common mode port. Additionally, the common mode port can represent the inverting and noninverting output port shorted together. Similarly, the PFET 162 can represent the PFET 142 or the PFET 144, whereby a gate and a drain of the PFET 162 connect to the common mode port. Also, the varactor 166 can represent either the varactor 148 or the varactor 150, whereby the varactor 148 is connected between the tuning port and the common mode port.

As shown in FIG. 1B, the PFET 162 connects between the second supply V_{DD} and the common mode port, and the NFET 164 connects between the first supply V_{SS} and the common mode port. By virtue of these connections and impedances of the NFET 164 and the PFET 162, a common mode noise component in the form of alternating current (AC) variations in the first and second supplies V_{SS} and V_{DD} can appear at the common mode port.

FIG. 1C is a small signal impedance schematic 170 of the common mode equivalent shown in FIG. 1B according to the teachings herein. In FIG. 1C the NFET 164 is modeled by an impedance Z₂ 174 connected between the first supply V_{SS} and the common mode port, and the PFET 164 is modeled by an impedance Z₁ 172 connected between the second supply V_{DD} and the common mode port. By using an impedance divider analysis, the following equation (Eq. 1A) can be derived for the common mode voltage with push V′_{CM}:

$${V}_{CM}^{′} = {V}_{CM} + \frac{{Z}_{2}}{{Z}_{1} + {Z}_{2}} \cdot {N}_{VDD} \qquad Eq . 1 A$$

where V_{CM} is the common mode voltage due to the first and second supply voltages, V_{SS} and V_{DD}, without noise, and N_{VDD} is the is the noise voltage from the first and/or second supply voltages. The noise voltage represents the variations in the supply voltage which can give rise to push, variations in the oscillator frequency, as described above. By rewriting the divider ratio of the impedances in terms of a supply push coefficient α, Equation 1A can be recast as follows:

V′_{CM}=V_{CM}+α·N_{VDD}. Eq. 1B

A varactor can have a capacitance C_{VAR} determined by the voltage across its terminals. Defining a first voltage V₊ at one terminal of the varactor and a second voltage V₋ at another terminal of the varactor, the varactor capacitance C_{VAR} can be given by Equation 2:

C_{VAR}=h(V₊−V₋) Eq. 2

where h(·) is a non-linear capacitance transfer function.
By identifying the first voltage V₊ with the common mode voltage with push V′_{CM} and the second voltage V₋ with the tuning voltage Vtune, the varactor capacitance C_{VAR} can be written as follows (Eq. 3A):

C_{VAR}=h(V′_{CM}−Vₜᵤₙₑ). Eq. 3A

Using Equation 1B, Equation 3A can be recast as

C_{VAR}=h([V_{CM}+α·N_{VDD}]−Vₜᵤₙₑ), Eq. 3B

and rearranging terms, Equation 3B becomes

$${C}_{VAR} = h ( {V}_{CM} - \overbrace{[ {V}_{tune} - α \cdot {N}_{VDD} ]}^{{V}_{tune}^{′}} ) . \qquad Eq . 3 C$$

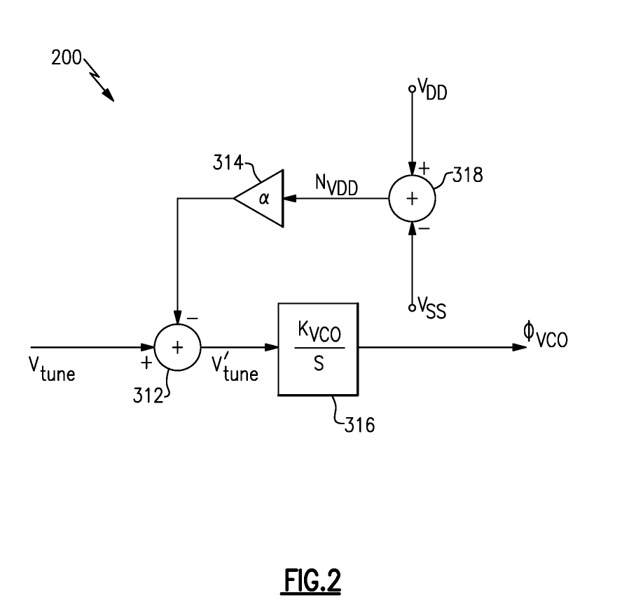

FIG. 2 is a system diagram 200 of a VCO according to the teachings herein. The system diagram includes a summing junction 312, a gain block 314, a differencing junction 318, and a VCO transfer function block 316. As shown in FIG. 2, the summing junction 318 shows the summing of noise from the first and second supplies V_{SS} and V_{DD}. The summed noise or push is expressed by the noise voltage N_{VDD} and is multiplied times the push coefficient α; the supply push noise term α·N_{VDD} is added to Vtune to give V′tune, the tuning voltage with push from Eq. 3C. Here Vtune can represent the tuning voltage without push and can also be referred to as an uncorrupted tuning voltage.

The system diagram 200 relates the uncorrupted tuning voltage Vtune to the tuning voltage with push V′tune through the summing junction 312, which adds the noise output from gain block 314 with the uncorrupted tuning voltage Vtune. Also, the tuning signal with push V′tune is multiplied by the VCO transfer function Kvco divided by “s” to give rise to the VCO output phase φ_{VCO}. Here the division by “s” represents the Laplace transform of an integral in the s-plane. Also, K_{VCO} has units of frequency divided by volts. The system diagram 200 can indicate that a VCO output will have variations in phase and in frequency due to the tuning signal with push V′tune.

An estimate of the transfer function value, the push coefficient α, can be derived either from theory, SPICE (simulation program with integrated circuit emphasis) simulations, or from common practice laboratory measurements. A typical value for the push coefficient a can be 0.5; however, for an NMOS cross coupled pair with a tank center-tap bias, a can be nearly equal to unity. In other circuit configurations a can be nearly 0. A range of values of a can be between 0 and 1.

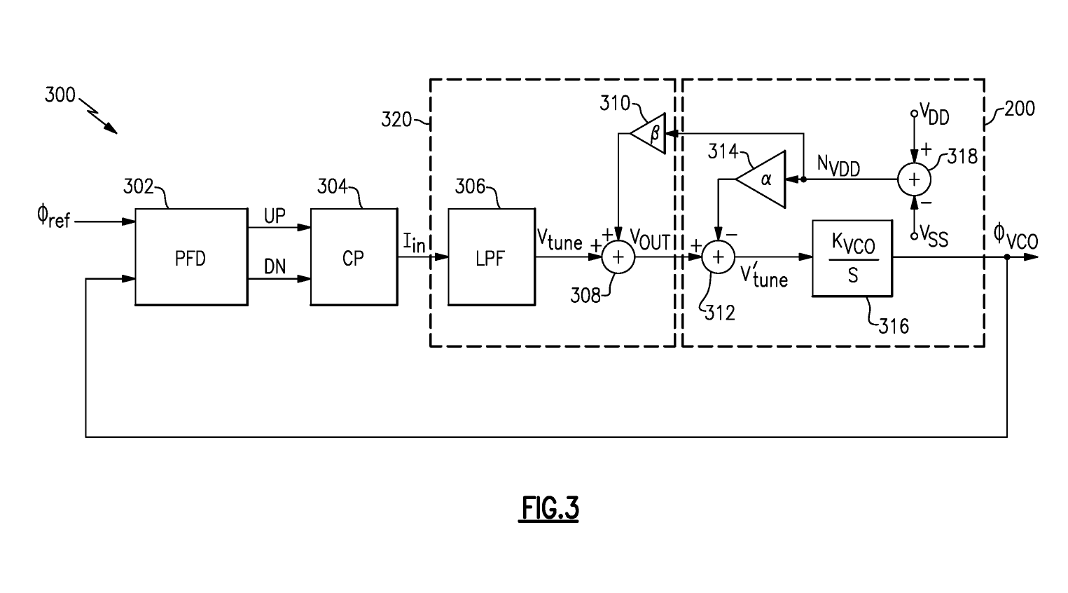

FIG. 3 is a system diagram of a PLL 300 with a VCO 200 and filter 320 according to the teachings herein. The PLL 300 includes a phase frequency detector (PFD) 302, a charge pump (CP) 304, the filter block 320, and the VCO 200. The filter block 320 includes a low pass filter (LPF) 306, a summing junction 308, and a gain block 310. The VCO 200 includes the summing junction 312, the gain block 314, the summing junction 318, and the VCO transfer function block 316.

In the steady state, the PLL 300 compares and locks a phase reference signal φ_{ref} with the VCO phase output φ_{VCO} by adjusting the pump up and pump down signals UP, DN. In response to the pump up signal UP and pump down signal DN, the charge pump (CP) 304 provides a pump current signal Iin at the input of the low pass filter (LPF) 306. The summing junction 308 adds a compensating term βN_{VDD} to the uncorrupted tuning voltage Vtune so as to compensate for the supply push noise term α·N_{VDD}.

Equations 4A and 4B show the resulting equation from a system level analysis of the filter 320 with the VCO 200 of FIG. 3. These equations quantify the push noise and compensating terms as the difference of the push coefficient a minus the compensating coefficient β times the push noise voltage N_{VDD}: and

V′ₜᵤₙₑ=Vₜᵤₙₑα·N_{VDD}+β·N_{VDD} Eq. 4A

V′ₜᵤₙₑ=Vₜᵤₙₑ−(α−β)·N_{VDD}. Eq. 4B

Hence a push factor can be defined as the push coefficient α minus the compensating coefficient β; and reducing push in a VCO and/or a VCO in a PLL becomes a practical realization of a circuit for creating the compensating coefficient β. Accordingly, the teachings herein describe circuits and filter circuits for realizing a compensating coefficient β.

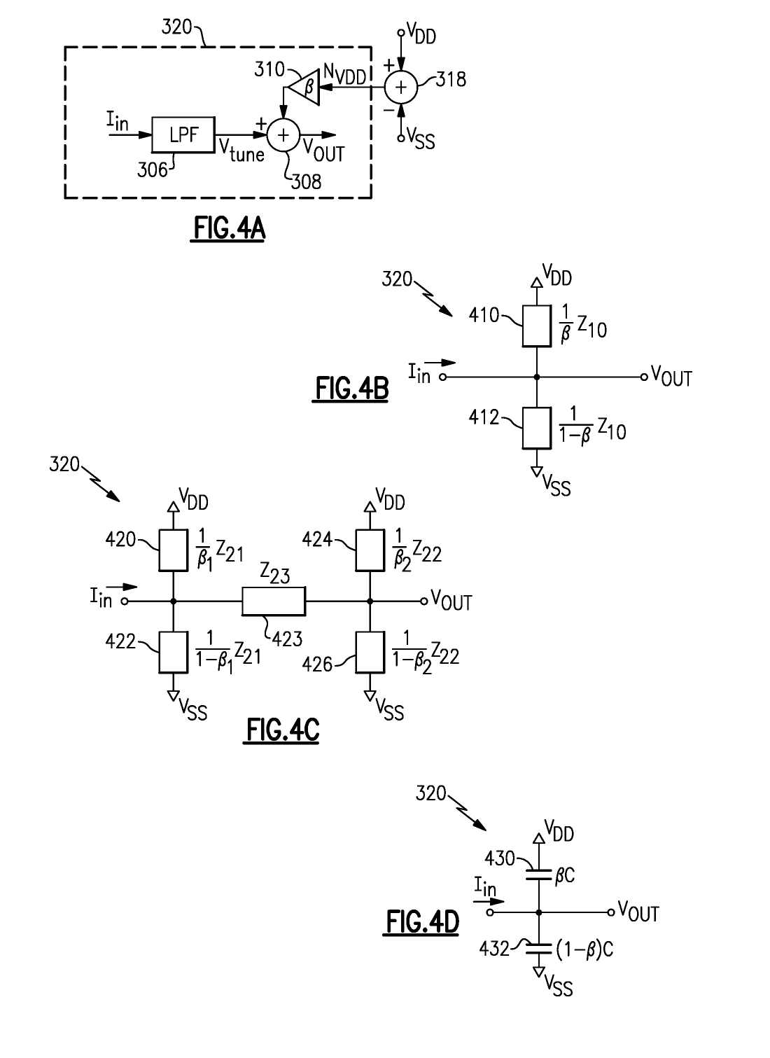

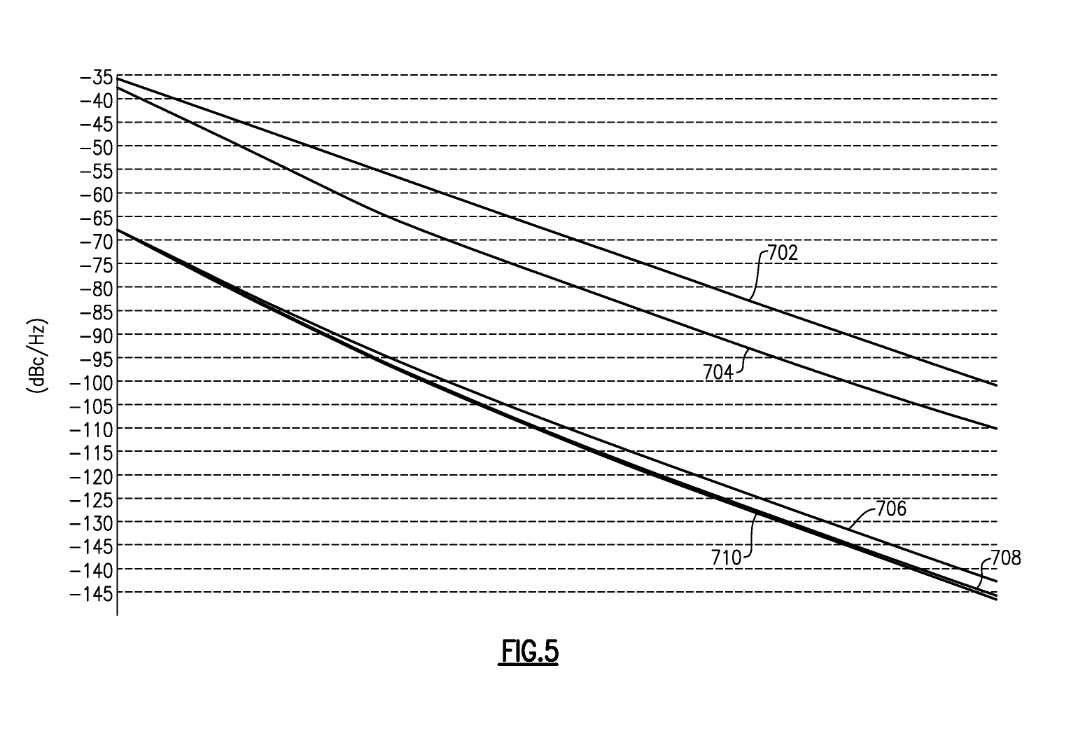

FIG. 4A is a system diagram of a filter 320 showing a system-level synthesis approach with a compensating coefficient β according to the teachings herein. As described with respect to FIG. 3, a way to reduce supply push is to reduce the term (α−β) in Equation 4B by realizing a circuit which provides a compensating coefficient β equal to or almost equal to the push coefficient α. FIG. 4A shows the system level concept for reducing push by introducing the compensating coefficient β into the filter 320 having an ideal low pass filter (LPF) 306. FIG. 4A

FIG. 4B is an impedance schematic of a filter 320 according to an embodiment. The impedance schematic shows a practical filter circuit which can both operate as a filter for a tuning voltage of a VCO and also be configured to generate a compensating coefficient β. The filter 320 includes a first impedance 410, connected between the second supply V_{DD} and a filter input/output port, and a second impedance 412, connected between the first supply V_{SS} and the filter input/output port. The filter input/output port receives the pump current signal Iin and provides the voltage V_{OUT}.

The selection of the values of the first impedance 410 and the second impedance 412 can be tailored to accomplish the synthesis configuration shown in FIG. 4A. The filter transfer function can be made equal to Z₁₀ while also introducing the compensating term βN_{VDD}. A synthesis approach as shown in FIG. 4B use a first impedance 410 having a value equal to Z₁₀ divided by the compensating coefficient β and a second impedance 412 having a value equal to Z₁₀ divided by unity minus the compensating coefficient β.

Comparing FIG. 4B to FIG. 4A, it can be seen that the compensating coefficient β is introduced through the first impedance 410 and the second impedance 412 by virtue of the divider ratio formed by their impedances. The divider ratio is synthesized to equal the compensating coefficient β so that the push noise voltage N_{VDD} from the second supply V_{DD} and/or the first supply V_{SS} is multiplied times β and provided to the input/output port. As shown in FIG. 4B, the divider ratio of the first impedance 410 to the total sum of the first impedance 410 and the second impedances 412 gives the desired mathematical result of βN_{VDD}.

Also, by comparison with FIG. 4A, FIG. 4B shows that the filter transfer function between the output voltage V_{OUT} and the pump input current Iin is equivalent to a shunt impedance with value Z₁₀. Additionally, with reference to FIG. 4A, FIG. 4B can provide a circuit synthesis approach for generating a filter 320 to compensate for a push coefficient a in the VCO 200. The shunt impedance Z₁₀ can be formed with passive elements such as capacitors.

Although, the filter 320 of FIG. 4B shows a first impedance 410 and a second impedance 412, more complex filter networks can be synthesized using additional impedances. Impedances connected in series between the first supply V_{SS} and the second supply V_{DD} can be arranged to replace shunt elements in T-networks and/or Pi-networks. In this way, the network filter transfer function can be preserved while allowing the introduction of a compensating coefficient. For instance, FIG. 4C shows an example of a higher-order filter using the above described synthesis approve.

FIG. 4C is an impedance schematic of a filter 320 according to another embodiment. The filter 320 includes a first impedance 420, a second impedance 422, a third impedance 423, a fourth impedance 424, and a fifth impedance 426 forming a filter network which can be of higher order than the filter 320 of FIG. 4B. As shown in FIG. 4C the first impedance 420 and the second impedance 422 are connected between the first supply V_{SS} and the second supply V_{DD} so as to create a filter shunt element having an equivalent shunt impedance of Z₂₁ while also introducing a first compensating coefficient β₁. Also, as shown in FIG. 4C the fourth impedance 424 and the fifth impedance 426 are connected between the first supply V_{SS} and the second supply V_{DD} so as to create a filter shunt element having an equivalent shunt impedance of Z₂₂ while also introducing a second compensating coefficient β₂. The third impedance 423 is a series element having impedance Z₂₃ in the filter 320. Introducing the two compensating coefficients β₁ and β₂ can advantageously allow an additional degree of freedom in canceling or reducing the effect of a push coefficient a in the VCO 200.

FIG. 4D is a circuit schematic of a filter 320 based on the embodiment of FIG. 4B. The filter 320 of FIG. 4D includes a first capacitor 430 and a second capacitor 432 so as to realize a first-order-filter capacitor implementation of the filter 320 of FIG. 4B.

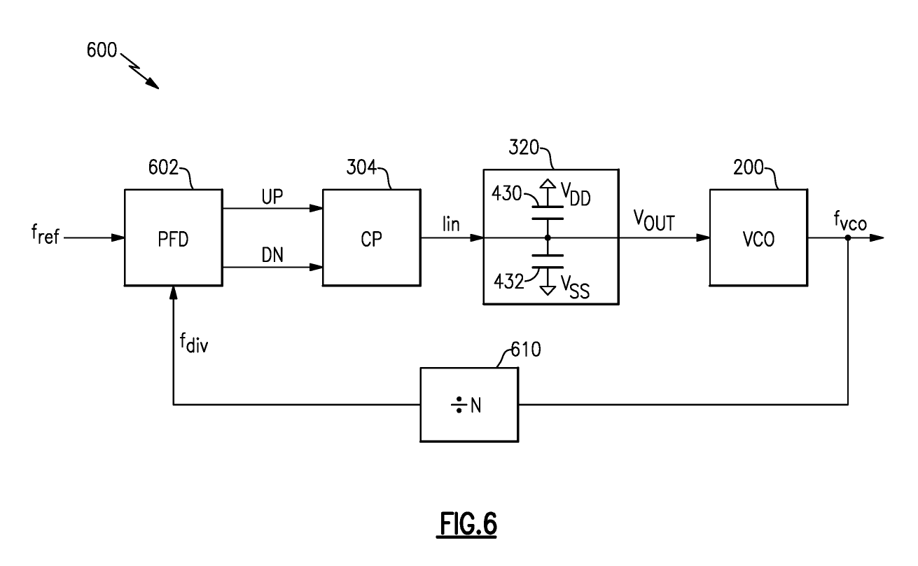

FIG. 5 is a relative plot of simulated phase noise vs. carrier offset frequency comparing an embodiment of the teachings herein. In all cases SPICE simulations of VCO pushing are performed on a PLL having a VCO and a low pass loop filter with a capacitor divider. The parameters varied in the simulations are the supply noise N_{VDD} and the compensating coefficient β.

Case 710 is a plot of simulated phase noise of the VCO without supply noise injection and can represent a simulated ideal noiseless-supply limit. Case 702 and case 704 are phase noise simulations where a disproportionately large amount of noise is intentionally injected on the VCO supply with the purpose that supply noise be a dominant noise contributor in the results. Case 702 corresponds to a PLL having a typical loop filter and with a compensating coefficient β set equal to zero. Case 704 corresponds to a PLL similar to that of Case 702, except the compensating coefficient β is set to be approximately equal, or very close in value, to the push coefficient α. Case 706 is similar to Case 702 in that it has the phase noise of Case 710; but Case 706 uses a different amount of supply noise and sets the compensating coefficient β equal to zero. In Case 706, the different amount of supply noise can be an amount representing a realistic or practical amount of supply noise. Case 708 is similar to Case 706, except the compensation coefficient β is set to be approximately equal, or very close in value, to the push coefficient α (β≅α).

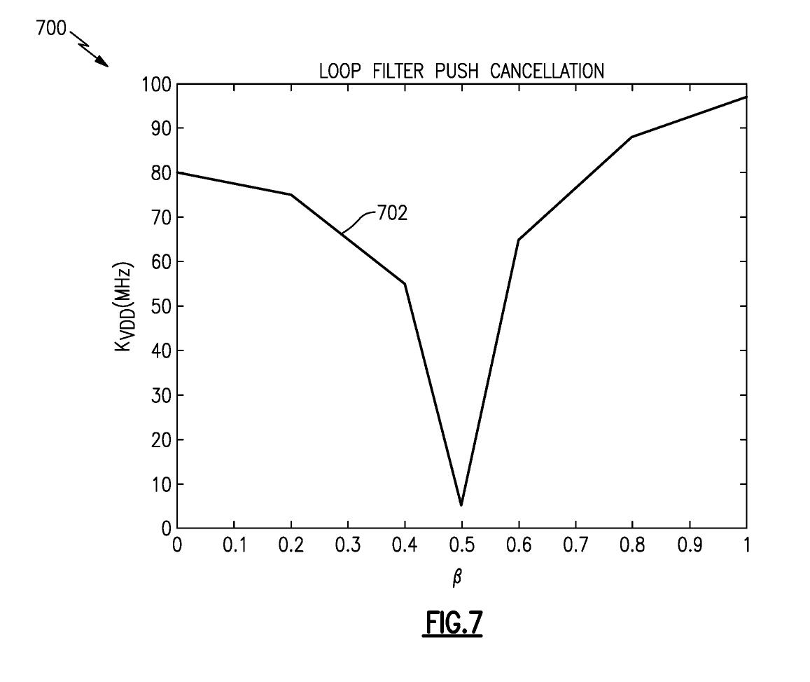

FIG. 6 is a top-level diagram of a PLL 600 including the loop filter 320 with a capacitor divider in accordance with the teachings herein. The PLL 600 has a phase frequency detector (PFD) 602 which compares a signal of reference frequency f_{ref} to a signal of frequency f_{div} from an output of a frequency divider block 610. The PLL can lock the signal of frequency f_{div} to the signal of reference frequency f_{ref} so as to provide an output signal of frequency f_{VCO} which is N times that of f_{ref}. The PFD 602 provides signals UP and DN to a charge pump (CP) 304, which in turn provides a current signal Iin to an input of the loop filter 320. In response to the current signal Iin, the loop filter 320 provides an output voltage Vout at the output of the loop filter 320. The voltage controlled oscillator (VCO) 200, in response to the output voltage Vout provided to the tuning port of the VCO 200, provides the output signal of frequency f_{VCO} at an output port of the VCO 200. The output voltage Vout can be equal to the tuning voltage Vtune of FIG. 1A.

In the PLL 600 VCO pushing from the first and second supplies V_{SS} and V_{DD} is reduced by intentionally introducing noise at the tuning port via signal Vout. The capacitor divider formed by a first capacitor 430 and a second capacitor 432 allows noise from the first and second supplies V_{SS} and V_{DD} to be provided to the tuning port of the VCO 200.

FIG. 7 is a graph 700 of SPICE simulated VCO supply push gain K_{VDD} 702 versus compensation coefficient β according to an embodiment. As shown in FIG. 700, a value of β close to 0.5 can reduce the supply push gain K_{VDD} by almost a factor of 10. Reducing K_{VDD} can correspond to reducing the difference between a push coefficient α and a compensating coefficient β as described above.

### Applications

Devices employing the above described VCO with filter circuits to reduce VCO pushing can be implemented into various electronic devices. Examples of the electronic devices can include, but are not limited to, consumer electronic products, parts of the consumer electronic products, electronic test equipment, etc. Examples of the electronic devices can also include circuits of optical networks or other communication networks. The consumer electronic products can include, but are not limited to, an automobile, a camcorder, a camera, a digital camera, a portable memory chip, a washer, a dryer, a washer/dryer, a copier, a facsimile machine, a scanner, a multifunctional peripheral device, etc. Further, the electronic device can include unfinished products, including those for industrial, medical and automotive applications.

The foregoing description and claims may refer to elements or features as being “connected” or “coupled” together. As used herein, unless expressly stated otherwise, “connected” means that one element/feature is directly or indirectly connected to another element/feature, and not necessarily mechanically. Likewise, unless expressly stated otherwise, “coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected).

Although this invention has been described in terms of certain embodiments, other embodiments that are apparent to those of ordinary skill in the art, including embodiments that do not provide all of the features and advantages set forth herein, are also within the scope of this invention. Moreover, the various embodiments described above can be combined to provide further embodiments. In addition, certain features shown in the context of one embodiment can be incorporated into other embodiments as well. Accordingly, the scope of the present invention is defined only by reference to the appended claims.

What is claimed is:

1. An apparatus comprising:
a VCO having a supply node configured to receive a supply voltage, a tuning port configured to receive a tuning voltage, and an output port configured to provide an output signal having a VCO output frequency;
a filter having an output port electrically connected to the tuning port, wherein the filter is configured to provide the tuning voltage having a filter supply injected component such that the filter supply injected component compensates for variations in the VCO output frequency in response to variations in the supply voltage.

2. The apparatus of claim 1, wherein the VCO further comprises a voltage controlled circuit element electrically connected between the output port and the tuning port such that an element voltage between the output port and the tuning port controls the VCO output frequency.

3. The apparatus of claim 2, wherein the voltage controlled circuit element is a varactor.

4. The apparatus of claim 2, wherein the output signal has a VCO common mode supply noise component and wherein the filter supply injected component is commensurate to the VCO common mode supply noise component such that variations in the element voltage are reduced.

5. The apparatus of claim 1, wherein the filter further comprises:
a first impedance;
a second impedance; and
wherein the first impedance and the second impedance are electrically connected in series to form a divider between the supply node and a common node such that the divider has a divider node electrically connected to the output port of the filter.

6. The apparatus of claim 5, wherein the divider is configured to provide the filter supply injected component at the divider node such that the supply injected component depends, at least in part, upon the first impedance and the second impedance.

7. The apparatus of claim 6, wherein the divider provides the filter supply injected component at the divider node based upon an intrinsic VCO transfer characteristic of the output signal at the output node of the VCO to a noise signal at the supply node.

8. The apparatus of claim 6, wherein the first and second impedances are capacitors.

9. The apparatus of claim 2, wherein the VCO and the filter are part of an integrated phase locked loop.

10. An apparatus comprising:
a VCO comprising:
a supply node configured to receive a supply voltage;
a tuning port configured to receive a tuning voltage;
a first output port configured to provide a first output signal having a VCO output frequency; and
a second output port configured to provide a second output signal complementary in phase to the first VCO output signal and having the VCO output frequency; and
a filter comprising:
a first impedance electrically connected between the supply node and the tuning port; and
a second impedance electrically connected between the ground node and the tuning port, wherein the first impedance and the second impedance are configured to provide the tuning voltage having a filter supply injected component from the supply rail onto the tuning port, and wherein the filter supply injected component reduces a supply push of the VCO.

11. The apparatus of claim 10, wherein the VCO further comprises:
a first voltage controlled circuit element electrically connected between the first output port and the tuning port;
a second voltage controlled circuit element electrically connected between the second output port and the tuning port;
wherein the VCO output frequency is determined, at least in part, by a first differential voltage between the first output port and the tuning port and a second differential voltage between the second output port and the tuning port.

12. The apparatus of claim 11, wherein the first voltage controlled circuit element and the second voltage controlled circuit element are varactors.

13. The apparatus of claim 11,
wherein the first output signal has a VCO common mode supply injected component and the second output signal has the VCO common mode supply injected component; and
wherein the filter supply injected component is commensurate to the VCO common mode supply injected component such that variations in the first differential voltage and the second differential voltage due to variations in the VCO common mode supply injected component are reduced.

14. The apparatus of claim 13,
wherein the filter is interposed between a phase locked loop charge pump and the VCO such that the tuning voltage has a PLL tuning component; and
wherein the first differential voltage and the second differential voltage vary in response to variations in the PLL tuning component such that the PLL tuning component controls the VCO output frequency.

15. The apparatus of claim 11,
wherein the first impedance is a capacitor having a first capacitance;
wherein the second impedance is a capacitor having a second capacitance;
wherein a filter response of the filter is determined, at least in part, by the sum of the first and the second capacitance;
wherein the first impedance and the second impedance are electrically connected in series to form a capacitor divider between the supply node and the ground node; and
wherein the capacitor divider is configured to provide the tuning voltage having a filter supply injected component from the supply rail onto the tuning port.

16. The apparatus of claim 15, wherein the filter supply injected component depends upon the first capacitance, the second capacitance, and the supply voltage.

17. The apparatus of claim 16,
wherein the capacitor divider provides the filter supply injected component based upon a first transfer characteristic of the first output signal to a noise signal of the power supply node; and
wherein the first transfer characteristic of the first output signal to the noise signal of the power supply node is equivalent to a second transfer characteristic of a second output signal to a noise signal of the power supply node.

18. The apparatus of claim 11, wherein the VCO and the filter are part of an integrated phase locked loop.

19. A voltage controlled oscillator circuit comprising:
an oscillator that receives a supply voltage with a variable component and an input voltage and provides an output signal having a frequency, wherein the oscillator includes an impedance circuit with at least one active impedance component that has a variable impedance based upon the input voltage and the supply voltage such that the input voltage and the supply voltage varies the impedance of the active impedance component and thereby varies the frequency of the output signal;
a filter that provides the input voltage to the oscillator, wherein the filter receives the supply voltage and wherein a filtered component of the supply voltage is provided to the impedance circuit from the filter so as to offset the variable component of the supply voltage received by the at least one active impedance component.

20. The circuit of claim 19, wherein the filter includes a capacitive filter that provides a capacitance between the supply voltage and the input voltage and between the input voltage and the ground.
